(19) United States
(12) Patent Application Publication
(10) Pub. No.: US 2016/0118566 A1
(43) Pub. Date: Apr. 28, 2016

(54) WEARABLE DEVICE HAVING THERMOELECTRIC GENERATOR

(71) Applicant: SAMSUNG ELECTRONICS CO., LTD., Suwon-si (KR)

(72) Inventors: Eunkyung LEE, Seoul (KR); Byounglyong CHOI, Seoul (KR); Wooram HONG, Yongin-si (KR); Junghan KIM, Suwon-si (KR); Dohun CHA, Yongin-si (KR)

(73) Assignee: SAMSUNG ELECTRONICS CO., LTD., Suwon-si (KR)

(21) Appl. No.: 14/822,554

(22) Filed: Aug. 10, 2015

(30) Foreign Application Priority Data
Oct. 23, 2014 (KR) 10-2014-0144287

(51) Int. Cl. H01L 35/30

(52) U.S. Cl. CPC H01L 35/30

(57) ABSTRACT

Provided are wearable devices including a thermoelectric generator. The wearable devices include a main body that has at least one opening and a thermoelectric generator that is seated in the opening. The devices include a pair of terminals that are electrically connected to an adjacent thermoelectric generator or a charge unit disposed on the main body, and a supporting member that is situated on a lower part of the thermoelectric generator and contacts the skin of a user, such that the thermoelectric generator includes a high temperature unit and a low temperature unit facing each other, and the high temperature unit is situated on the supporting member and the low temperature unit is disposed to face an outside environment.

### CROSS-REFERENCE TO RELATED APPLICATION(S)

This application claims the benefit under 35 U.S.C. §119(a) of Korean Patent Application No. 10-2014-0144287 filed on Oct. 23, 2014, in the Korean Intellectual Property Office, the entire disclosure of which is incorporated herein in by reference for all purposes.

### BACKGROUND

1. Field

The following description relates to wearable devices having a thermoelectric generator.

2. Description of Related Art

A thermoelectric generator uses a thermoelectric conversion phenomenon to function. The thermoelectric conversion is an energy conversion between electrical energy and thermal energy. The generation of electricity when there is a temperature difference between both ends of a thermoelectric material is referred to as a Seebeck effect. In contrast, the temperature reduction due to a temperature difference that occurs between both ends of a thermoelectric material when current is applied to flow through the thermoelectric material is referred to as a Peltier effect. The thermoelectric conversion phenomenon, which includes the above-described Seebeck and Peltier effects, is a reversible conversion between energy associated with heat and electricity and is a direct energy conversion. The phenomenon is generated by the movement of electrons and/or holes in the interior of a piece of thermoelectric material.

When the Seebeck effect is used, heat generated by the operation of computers, engines of automobiles, or other machines that produce waste heat from various industries may be converted to useful electrical energy. As the interest on new energy development, recovery of waste energy, and environmental protection when generating energy increases, the interest and applicability of thermoelectric devices increases. For example, use of thermoelectric devices offers the ability to exploit energy that would otherwise merely be wasted.

The efficiency of a thermoelectric generator is determined by a figure of merit of a thermoelectric material, that is, a ZT coefficient of a thermoelectric material. Such a dimensionless ZT coefficient is expressed as the following Equation 1.

$$ZT = \frac{{S}^{2} σ}{k} T \qquad Equation 1$$

In Equation 1, the ZT coefficient is proportional to the Seebeck coefficient of the thermoelectric material S and the electrical conductivity of the thermoelectric material a, and is inversely proportional to thermal conductivity of the thermoelectric material k. The Seebeck coefficient S indicates a magnitude of a voltage dV/dT generated according to unit temperature variations of the thermoelectric material.

As computer systems have improved to simultaneously have high performance traits and be miniaturized, and as techniques of improved display devices and image communication have been developed, wearable computing devices that can be worn by a user have developed. For example, smart watches that can be worn on the wrist and smart glasses that can be worn on the head have been developed. Such smart devices include small, wearable processors and displays that allow such devices to provide processing and interactivity while being highly portable.

Such wearable devices include an electronic module that provides predetermined information to the user and a wearable structure that is configured to be worn by the user. As discussed, such a wearable structure may take the form of a wristwatch or glasses, but other structures such as a necklace are also possible.

Recently, interest has increased with respect to various wearable-type devices, such as wrist-watch type smart devices including smart phones. A wearable device like a wrist watch is designed to be suitable for fitting onto a human body in design aspects such as shape, size, and weight since the wearable device is to be worn on a human body. Due to this requirement, at present, the capacity of a battery of the wearable device is insufficient for operation for a long period of time, and thus, the battery of the wearable device is frequently recharged.

An energy harvesting technique that uses clean energy, such as light, heat, or kinetic energy, is a relevant candidate for an energy source of mobile devices. In particular, in the case of a thermoelectric device that uses the heat of a human body to produce electrical energy for a wearable device, the heat of the human body may be an endless and simple energy source as long as there is a temperature difference produced by the heat of the human body. Thus, a thermoelectric device that derives energy form heat produced by the human body may be a future suitable energy source for wearable devices. In the case of a wristwatch-type smart device, a battery of the wristwatch-type smart device may be charged by using the heat of a human body by mounting a thermoelectric device inside or on a strap of the wristwatch-type smart device. Such a thermoelectric device is then in contact with the user's wrist, so as to harvest energy from heat produced by the human body.

However, when a thermoelectric generator is mounted on a wearable device, a temperature difference between both ends of the thermoelectric generator is small, and thus, the charge efficiency of the wearable device may be insufficient to produce enough energy to meet the power requirements of the wearable device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Provided are wearable devices that include a thermoelectric generator, the generation efficiency of which is improved by maintaining a large temperature difference between high and a low temperature units of the thermoelectric generator. The large temperature difference is maintained by disposing the low temperature unit relatively close to external air.

Additional aspects are set forth in part in the description which follows and, in part, are apparent from the description, or are learned by practice of the presented examples.

In one general aspect, a wearable device includes a main body having at least one opening, a thermoelectric generator that is seated in the opening and includes a pair of terminals that are electrically connected to an adjacent thermoelectric generator or a charge unit that is disposed on the main body, and a supporting member that is in contact with the skin of a user on a lower part of the thermoelectric generator, wherein the thermoelectric generator includes a high temperature unit and a low temperature unit facing each other, and the high temperature unit is disposed on the supporting member and the low temperature unit is disposed to face an outside environment.

The supporting member may include a pair of vertical units that extend perpendicularly to the supporting member from the supporting member, and a pair of protrusion units that extend towards opposite sides of the opening from an upper part of the vertical units, wherein the main body comprises a pair of grooves to correspond to the pair of protrusion units, the pair of protrusion units being inserted into the pair of grooves.

The pair of terminals may be inserted into the pair of grooves.

The pair of terminals may be respectively disposed on the pair of protrusion units.

The pair of terminals may include a p-type terminal and an n-type terminal, and the n-type terminal may be electrically connected to a p-type terminal of another thermoelectric generator in an adjacent opening.

The supporting member may be formed of plastic.

The wearable device may further include a protection member or a heat sink situated on the thermoelectric generator.

The heat sink may be formed of a material comprising one or more of a metal, carbon, carbon nanotubes (CNT), graphite, and graphene.

The wearable device may further include a plurality of metal vias that fill a plurality of through holes in the supporting member, wherein the metal vias are in contact with the high temperature unit and are configured to transmit heat of the user's skin to the high temperature unit.

The main body may be a strap that surrounds a wrist or a head of a human or an animal, and the opening and the thermoelectric generator may be formed to be longer in a width direction of the strap.

In another general aspect, a wearable device includes a main body including at least one opening groove formed along a surface of the main body away from the body of a user, and a thermoelectric generator including a high temperature unit on a bottom of the opening groove and a low temperature unit facing an outside environment, wherein the thermoelectric generator comprises a pair of terminals that are electrically connected to an adjacent thermoelectric generator or a charge unit disposed on the main body.

The pair of terminals of the thermoelectric generator may be inserted into a corresponding pair of sidewall grooves that is formed in sidewalls of the opening groove and may be electrically connected to a conductive unit disposed in the corresponding pair of sidewall grooves.

The pair of terminals may include a p-type terminal and an n-type terminal, and the n-type terminal may be connected to a p-type terminal of another thermoelectric generator disposed in an adjacent opening groove.

The wearable device may further include a protection member or a heat sink situated on the thermoelectric generator.

The heat sink may be formed of a material including one or more of a metal, carbon, carbon nanotubes (CNT), graphite, and graphene.

The wearable device may further include a plurality of first metal vias that fill a plurality of through holes formed on a bottom of the opening groove in the main body, wherein the first metal vias are in contact with the high temperature unit and are configured to transmit heat of the user's skin to the high temperature unit.

The main body may be a strap that surrounds a wrist or a head of a human or an animal, and the opening and the thermoelectric generator may be disposed to be longer in a width direction of the strap.

The pair of terminals may be disposed on the surface of the main body away from a user's body, and further comprise a protection member that covers the low temperature unit and extends along at least a portion of the surface of the main body away from a user's body.

The wearable device may further include an insulating layer that surrounds a gap between a p-type device and an n-type device and an outer circumference of the thermoelectric generator, a pair of second metal vias formed in the insulating layer that are configured to respectively contact the pair of terminals, and a pair of conductive units on a bottom of the opening groove and in contact with the pair of second metal vias.

In yet another general aspect, a wearable device includes a thermoelectric generator, including a high temperature unit and a low temperature unit, situated on a bottom of an opening of a main body having at least one opening, wherein the thermoelectric generator includes a pair of terminals that is electrically connected to an adjacent thermoelectric generator or charge unit that is disposed on the main body, and a supporting member that is in contact with the skin of a user on a lower part of the thermoelectric generator, wherein the high temperature unit is disposed on the supporting member and the low temperature unit is disposed to face an outside environment.

Other features and aspects will be apparent from the following detailed description, the drawings, and the claims.

### BRIEF DESCRIPTION OF THE DRAWINGS

FIG. 1 is a schematic plan view of a wearable device having a thermoelectric generator according to an example.

FIG. 2 is a cross-sectional view taken along line II-II of FIG. 1.

FIG. 3 is a perspective view showing an example of a supporting member of FIG. 1.

FIG. 4 is a schematic circuit of a wearable device according to an example.

FIG. 5 is a schematic plan view of a wearable device having a thermoelectric generator according to another example.

FIG. 6 is a schematic plan view of a wearable device having a thermoelectric generator, according to another example.

FIG. 7 is a cross-sectional view taken along line VII-VII of FIG. 6.

FIG. 8 is a cross-sectional view of the modified wearable device of FIG. 7.

FIG. 9 is a schematic plan view of a wearable device having a thermoelectric generator according to another example.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations described is an example; however, the sequence of and/or operations is not limited to that set forth herein and may be changed as is known in the art, with the exception of steps and/or operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Reference is now be made in detail to examples, which are illustrated in the accompanying drawings. In the drawings, the thicknesses of layers and regions are exaggerated for clarity. The examples are capable of various modifications and are potentially embodied in many different forms. It is intended to be understood that when an element or layer is referred to as being “on” another element or layer, the element or layer is situated directly on another element or layer or intervening elements or layers. Like reference numerals in the drawings denote like elements throughout the specification, and thus their description is omitted.

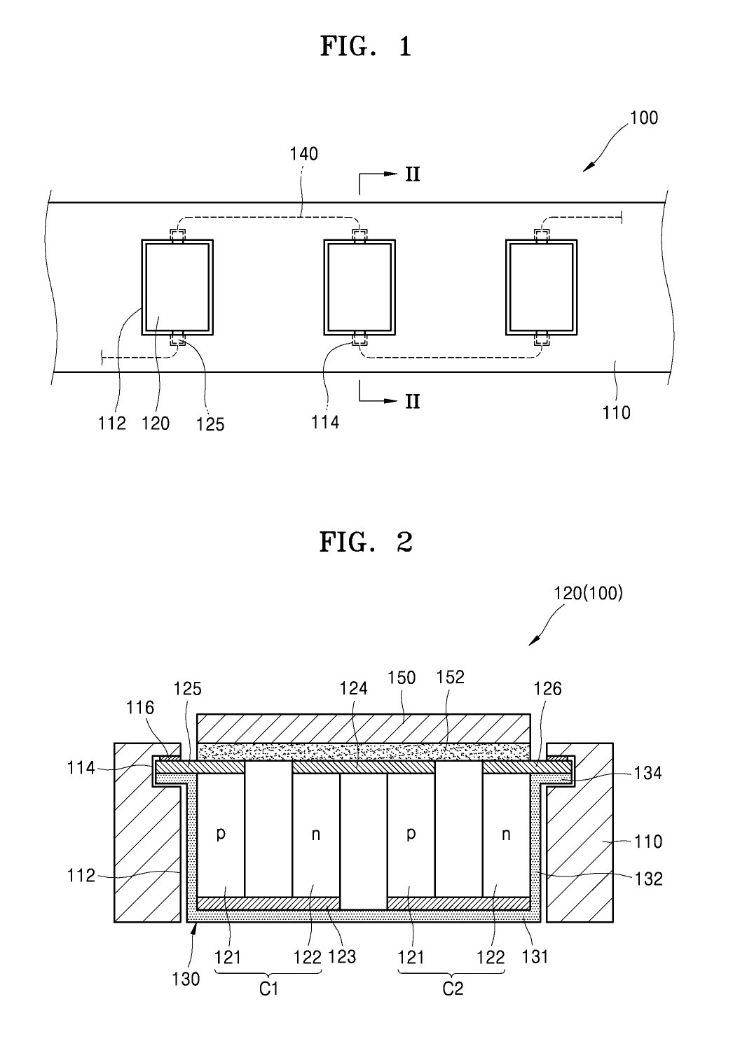

FIG. 1 is a schematic plan view of a wearable device 100 having a thermoelectric generator 120 according to an example. FIG. 2 is a cross-sectional view taken along line II-II of FIG. 1.

Referring to the example of FIG. 1, the wearable device 100 includes a main body and an electronic device disposed in the main body. In such an example, the main body is disposed to contact a human body or the skin of an animal. For example, the main body is a strap or a band that surrounds a wrist, an arm, a leg, a chest, or a head of a user, including a human being or an animal.

In examples, the main body is formed of rubber, plastic, or fabric. However, the main body is formed out of combinations of these materials or other, similar materials in other examples.

Hereinafter, a strap 110 that surrounds a wrist is referred to as the main body. The strap 110 includes at least one opening 112. In FIG. 1, for convenience of description, the strap 110 is depicted as having three openings 112. The thermoelectric generator 120 is disposed in each of the openings 112. For example, the electronic device is a charge unit 103, with reference to FIG. 4. Also, in the example of FIG. 1, the electronic device consumes electricity generated by the thermoelectric generator 120.

In the example of FIG. 1, the opening 112 is formed to be longer in a width direction of the strap 110. Also, in the example of FIG. 1, the thermoelectric generator 120 is formed to be longer in a width direction of the strap 110. When the strap 110 is worn, for example, on a wrist of the user, if the thermoelectric generator 120 is disposed so as to be longer in the width direction of the strap 110, the effect of the curvature of the wrist is reduced. As a result, the number of thermoelectric generators 120 is increased.

In some examples, a gap is formed between the opening 112 and the thermoelectric generator 120. In examples, such a gap is filled with air or aerogel.

Referring to the example of FIG. 2, the thermoelectric generator 120 includes at least a pair of a p-type semiconductor 121 and a corresponding n-type semiconductor 122. The pair of the p-type semiconductor 121 and the corresponding n-type semiconductor 122 is referred to as a cell. In FIG. 2, for convenience of description, the thermoelectric generator 120 having first and second cells C1 and C2 is depicted. Each of the first and second cells C1 and C2, as shown, includes a p-type semiconductor 121 and a corresponding n-type semiconductor 122.

The first and second cells C1 and C2 are connected to each other in a series. A lower electrode 123 is formed on lower parts of the p-type semiconductor 121 and the n-type semiconductor 122. Additionally, in the example of FIG. 2, an upper electrode 124 is formed on the p-type semiconductor 121 and the n-type semiconductor 122 of adjacent cells. However, the lower electrode 123 is disposed relatively close to the skin of a user to exchange heat with the skin. The lower electrode 123 is referred to as a high temperature unit or a hot junction, because it is in direct contact with the user's skin, which allows the user's body to transfer heat into the lower electrode 123.

The upper electrode 124 faces the lower electrode 123 and is disposed towards the outside, which is the exterior of the user's wrist. The upper electrode 124 is referred to as a low temperature unit or a cold junction.

In the example of FIG. 2, the thermoelectric generator 120 also includes a p-type terminal 125 and an n-type terminal 126 in order to connect the thermoelectric generator 120 to the outside of the user's wrist.

Additionally, a supporting member 130 is situated on a lower part of the thermoelectric generator 120. The supporting member 130 is present to help secure the physical structure of the thermoelectric generator 120. The supporting member 130 is formed of a hard material. For example, the supporting member is potentially formed from an appropriate type of plastic. In examples, the supporting member 130 contacts the user's skin.

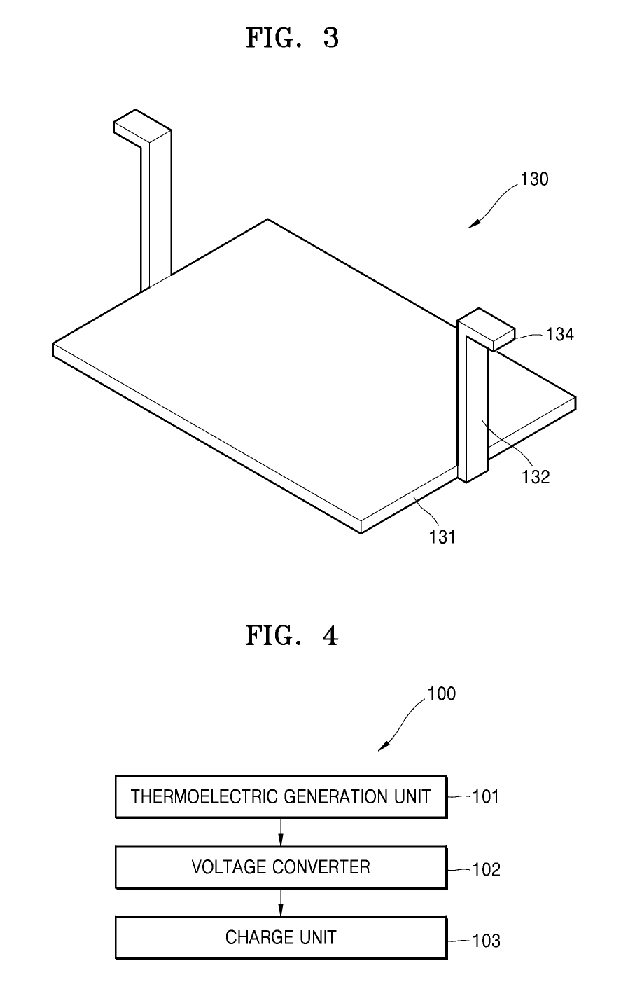

As shown in the example of FIG. 3, the supporting member 130 includes a main body unit 131 that supports the lower part of the thermoelectric generator 120, vertical units 132 that vertically extend from the main body unit 131, and protrusion units 134 that protrude outward from upper parts of the vertical units 132.

In examples, the p-type terminal 125 and the n-type terminal 126 are respectively disposed on the protrusion units 134. The p-type terminal 125 of a single cell is connected in series to the adjacent n-type terminal 126 of the adjacent cell via a wire 140, which is presented in FIG. 1.

In the example of FIG. 2, the p-type terminal 125 and the n-type terminal 126 are respectively disposed on different protrusion units 134. However, the disposition of the p-type terminal 125 and the n-type terminal 126 according to the examples is not limited to such an example. For example, in other examples, the p-type terminal 125 and the n-type terminal 126 are separately disposed on the same protrusion unit 134. In this case, the electrical connection to an adjacent thermoelectric generator 120 is facilitated.

In the example of FIG. 1, grooves 114 are formed in the strap 110 and the protrusion units 134 and the p-type terminal 125 and the n-type terminal 126 thereon are inserted into the grooves 114. A conductive unit 116 into which the p-type terminal 125 and the n-type terminal 126 are connected is formed in the groove 114. In such an example, the conductive unit 116 is connected to a wire 140.

In an example, the thermoelectric generators 120 are connected in series by the wires 140 disposed on the strap 110. In such an example, of the thermoelectric generators 120 connected in series, the p-type terminal 125 of the first thermoelectric generator 120 and the n-type terminal 126 of the final thermoelectric generator 120 are respectively connected to the charge unit 103.

An adhesive, not shown, is disposed between the supporting member 130 and the thermoelectric generator 120 in some examples. For example, the adhesive is formed of an appropriate thermal interface material (TIM).

Additionally, in an example, a heat sink 150 is further disposed on the thermoelectric generator 120. The heat sink 150 is formed of materials such as a metal, carbon, carbon nanotubes (CNTs), graphite, graphene, or a combination of these materials, or any other similar appropriate material that is used to function as heat sink 150. In such an example, an insulating adhesive 152 is formed under the heat sink 150 in order to fix the heat sink 150 onto the upper electrode 124. For example, the insulating adhesive 152 is formed of a TIM.

However, the heat sink 150 according to the examples is not limited thereto. A protection member, not shown, formed of an insulating material is formed as an alternative to the heat sink 150. Further, the protection member is possibly formed of an organic polymer, such as polyethylene, PVA, PDMA, plastic, an acryl group, a vinyl, and so on, or glass, fabric, oxide, nitride, wood, rubber, and so on.

Thus, the thermoelectric generator 120 includes a plurality of cells, as shown in FIG. 2, or alternative includes a single cell.

FIG. 4 is a schematic circuit of the wearable device 100 according to an example.

Referring to the example of FIG. 4, the wearable device 100 includes a thermoelectric generation unit 101, a voltage converter 102, and a charge unit 103.

As described above, the thermoelectric generation unit 101 includes at least one thermoelectric generator 120. As thermoelectric generators 120 have already been described, further description is omitted for brevity.

The voltage converter 102 controls the voltage that is supplied to the charge unit 103 by receiving the electricity generated by the thermoelectric generator 120. The voltage converter 102 is omitted in some examples.

The charge unit 103 stores electricity supplied from the voltage converter 102. For example, the charge unit 103 is a chargeable battery. Additionally, in an example, the charge unit 103 is a chargeable battery of an electronic device that is used in the wearable device 100.

However, the charge unit 103 according to the examples is not limited to these specific examples. For example, the charge unit 103 is used for storing electricity generated by the thermoelectric generator 120 and for charging external electronic devices. In an example, for charging the external electronic devices, another voltage converter is further provided in the charge unit 103.

In the thermoelectric generator 120 of the wearable device 100 according to the example of FIG. 1, the low temperature unit is disposed so as to be almost exposed to the outside of the user's wrist. The high temperature unit of the thermoelectric generator 120 is in direct contact with the skin of a wrist, a temperature of which is approximately 35° C. due to the user's body heat, and the low temperature unit is exposed to the outside, a temperature of which varies according to a temperature of the surrounding air. In a case of a typical thermoelectric generator, as time passes, a temperature difference between the high temperature unit and the low temperature unit is reduced, as the temperatures reach equilibrium. Accordingly, the thermoelectric effect is reduced because the thermoelectric effect is ordinarily driven by a temperature difference. However, since the low temperature unit of the thermoelectric generator 120 according to the example is almost exposed to the outside, the temperature of the low temperature unit is reduced by wind and other air circulation. Thus, the temperature difference between the high temperature unit and the low temperature unit is maintained at a certain level in accordance with the difference between an ambient temperature and the body temperature of the user. Accordingly, the power generation efficiency is of the thermoelectric generator 120 is increased.

Also, the temperature of the low temperature unit is potentially reduced by shaking the wearable device 100 that is worn on a wrist, due to improving air circulation. Thus, the power generation efficiency of the thermoelectric generation unit 101 is increased due to producing a larger temperature difference.

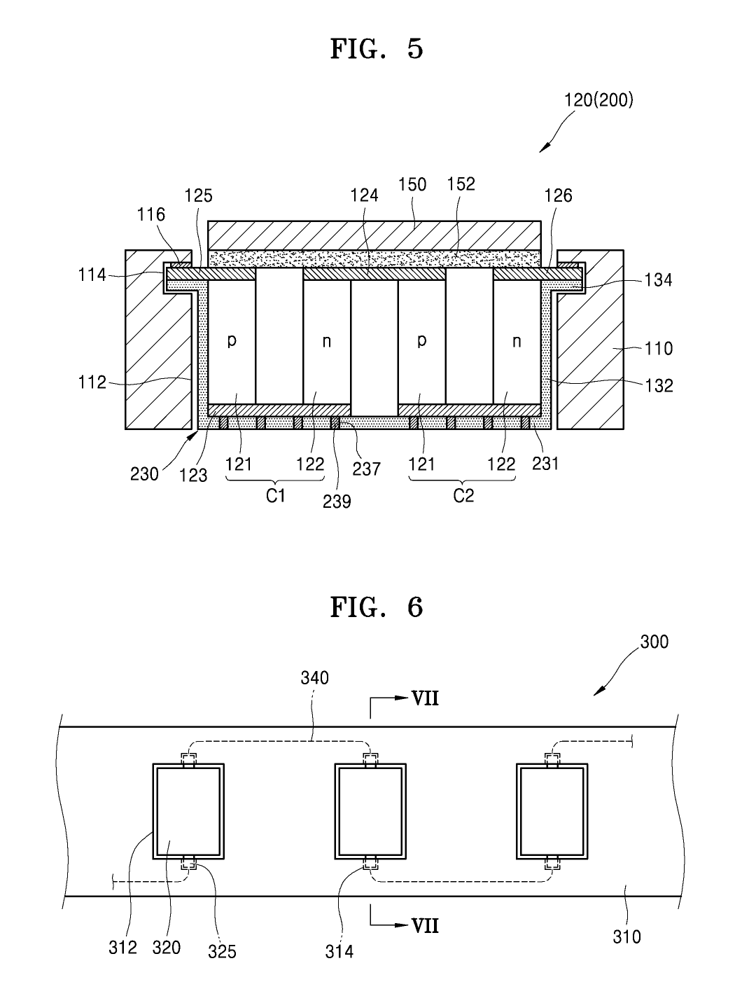

FIG. 5 is a schematic plan view of a wearable device 200 having a thermoelectric generator 120, according to another example. Like reference numerals are used to indicate elements that are substantially identical to the elements of FIGS. 1 through 4, and thus, detailed descriptions thereof are not repeated for brevity.

Referring to the example of FIG. 5, a plurality of metal vias 239 are substantially and vertically formed in a main body unit 231 of a supporting member 230. A via is an electrical connection between layers in a physical electronic circuit that goes through the plane of at least one adjacent layer. For example, the metal vias 239 in the main body unit 231 of the supporting member 230 promote heat transfer between a lower electrode 123 and the skin. In such an example, the metal vias 239 are formed by filling through holes 237 formed in the supporting member 230. However, the metal vias 239, according to this other example, are not limited to this single example. As an alternative, heat pipes are disposed instead of the metal vias 239.

Other structures and operations of the wearable device 200 are well understood from the descriptions above, and thus, detailed descriptions are not repeated for brevity.

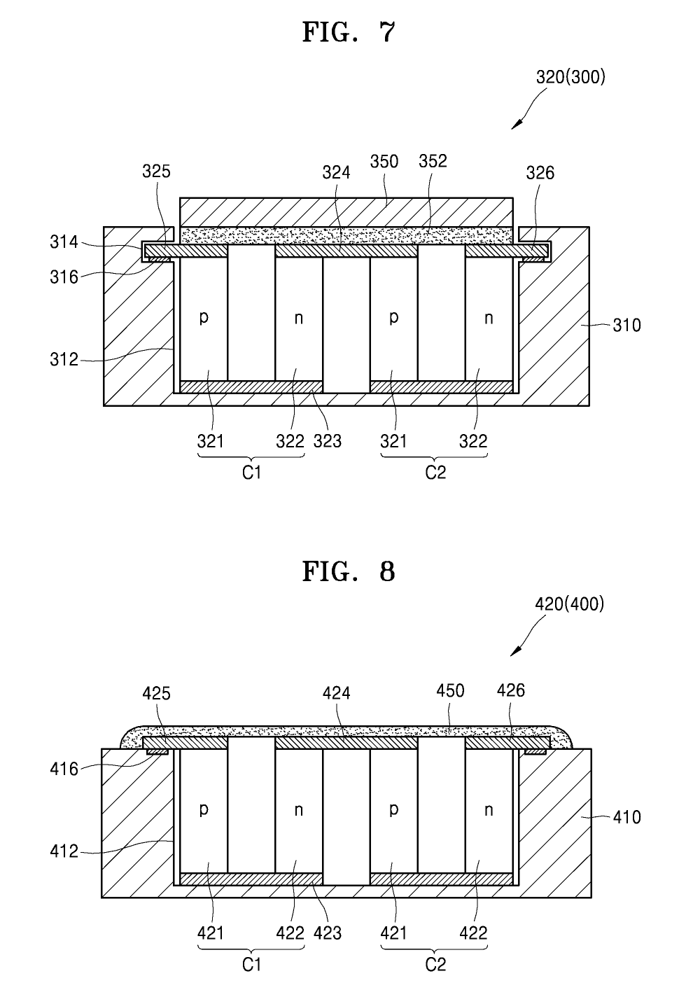

FIG. 6 is a schematic plan view of a wearable device 300 having a thermoelectric generator 320, according to another example. FIG. 7 is a cross-sectional view taken along line VII-VII of FIG. 6. Like reference numerals are used to indicate elements that are substantially identical to the elements of FIGS. 1 through 5. Thus the detailed descriptions of such substantially identical elements are not repeated for brevity.

Referring to the example of FIG. 6, the wearable device 300 includes a main body and an electronic device disposed in the main body. For example, the main body includes a strap 310. Hereinafter, a strap 310 that surrounds a wrist is described as the main body. At least one opening groove 312 is formed in the strap 310. FIG. 6, for convenience of description, depicts three opening grooves 312. In the example of FIG. 6, a thermoelectric generator 320 is disposed in each of the opening grooves 312. In such an example, such an electronic device is the charge unit 103, with reference to FIG. 4. Also, in this example, the electronic device consumes electricity generated by the thermoelectric generator 320.

For example, the opening groove 312 is formed to be longer in a width direction of the strap 310. Also, the thermoelectric generator 320 is also formed to be longer in the width direction of the strap 310. When the strap 310 is worn, for example, on a wrist of a user, if the thermoelectric generator 320 is disposed in the width direction of the strap 310, the effect of the curvature of the wrist may be reduced, and thus, the number of thermoelectric generators 320 is increased.

With reference to FIGS. 6 and 7, the thermoelectric generator 320 includes at least a pair of a p-type semiconductor 321 and an n-type semiconductor 322. The pair of the p-type semiconductor 321 and the n-type semiconductor 322 is referred to as a cell. In FIG. 6, for convenience of description, a thermoelectric generator 320 having first and second cells C1 and C2 is depicted. As shown in FIG. 6, the first and second cells C1 and C2 are connected to each other in a series. A lower electrode 323 is formed on lower parts of the p-type semiconductor 121 and the n-type semiconductor 122. Additionally, an upper electrode 324 is formed on the p-type semiconductor 321 and the n-type semiconductor 322 of adjacent cells and accordingly, connects the upper electrode 324 of the second cell C2 and the n-type semiconductor 322 of the first cell C1 to each other. The thermoelectric generator 320 includes a p-type terminal 325 and an n-type terminal 326 to connect the thermoelectric generator 320 to the outside. Also, the n-type terminal 326 of the first cell C1 is connected in series to the p-type terminal 325 of the second cell C2 by the upper electrode 324.

In the example of FIG. 6, the p-type terminal 325 of the first cell C1 and the n-type terminal 326 of the second cell C2 are respectively formed to protrude in an opposite direction to each other from the thermoelectric generator 320. Grooves 314 are formed in the strap 310 and accommodate the p-type terminal 325 of the first cell C1 and the n-type terminal 326 of the second cell C2. Also, in such an example, conductive units 316 are formed in the grooves 314 to electrically connect the grooves 314 to the p-type terminal 325 of the first cell C1 and to the n-type terminal 326 of the second cell C2.

In FIG. 6, the p-type terminal 325 of the first cell C1 and the n-type terminal 326 of the second cell C2 are disposed in different directions. However, the disposition of the p-type terminal 325 of the first cell C1 and the n-type terminal 326 of the second cell C2 according to the other example is not so limited. For example, the p-type terminal 325 of the first cell C1 and the n-type terminal 326 of the second cell C2 are formed to protrude in the same direction from the thermoelectric generator 320.

The thermoelectric generators 320 are connected in series by wires 340 disposed on the strap 310. Of the thermoelectric generators 320 connected in series, the p-type terminal 325 of the first thermoelectric generator 320 and the n-type terminal 326 of the final thermoelectric generator 320 are connected to the charge unit 103.

An adhesive, not shown, is optionally formed on a bottom of the opening groove 312 on a lower part of the thermoelectric generator 320. As in previous examples, in an example, the adhesive is formed of a TIM.

In such an example, a heat sink 350 is further disposed on the thermoelectric generator 320. The heat sink 350 is formed of a metal, carbon, CNT, graphite, graphene, or a combination of these materials, or any other similar appropriate material that is used to function as heat sink 350. Also, an insulating adhesive 352 is formed under the heat sink 350 to fix the heat sink 350 on the upper electrode 324. In this example, the insulating adhesive 352 is a TIM.

However, the heat sink 350 according to the other example is not limited thereto. A protection member, not shown, formed of an insulating material is formed instead of the heat sink 350. Here, the protection member is formed of an organic polymer, such as polyethylene, PVA, PDMA, plastic, an acryl group, vinyl, etc. glass, fabric, oxide, nitride, wood, rubber, and so on, or another appropriate material or combination of materials.

In the example of FIG. 5, the metal vias 239 are formed on the bottom of the opening grooves 312.

FIG. 8 is a cross-sectional view of the modified wearable device 400 of FIG. 7. Like reference numerals are used to indicate elements that are substantially identical to the elements of FIGS. 6 and 7, and thus detailed descriptions thereof are not repeated for brevity.

Referring to FIG. 8, a p-type terminal 425 of the first cell C1 and an n-type terminal 426 of the second cell C2 extend on an upper surface of a strap 410. Conductive units 416 are formed on regions of the strap 410 corresponding to the p-type terminal 425 of the first cell C1 and the n-type terminal 426 of the second cell C2. A protection member 450 is formed above opening groove 412 and covers the thermoelectric generator 420. The protection member 450 is formed to cover a portion or the whole upper surface of the strap 410. The protection member 450 is formed to be a thin layer using plastic, rubber, polymer, and similar protective substances. An adhesive, not shown, is further optionally formed between the protection member 450 and the thermoelectric generator 420 in some examples.

Although not shown, the protection member 450 potentially fills the opening groove 412 so as to insulate the p-type semiconductors 421 from the n-type semiconductors 422.

A heat sink 350, with reference to FIG. 7, is further disposed on the protection member 450.

However, the other example is not limited thereto. Alternatively, in another example, the upper electrode 424 and the p-type terminal 425 and the n-type terminal 426 of the thermoelectric generator 420 are formed higher than a height of the opening 412.

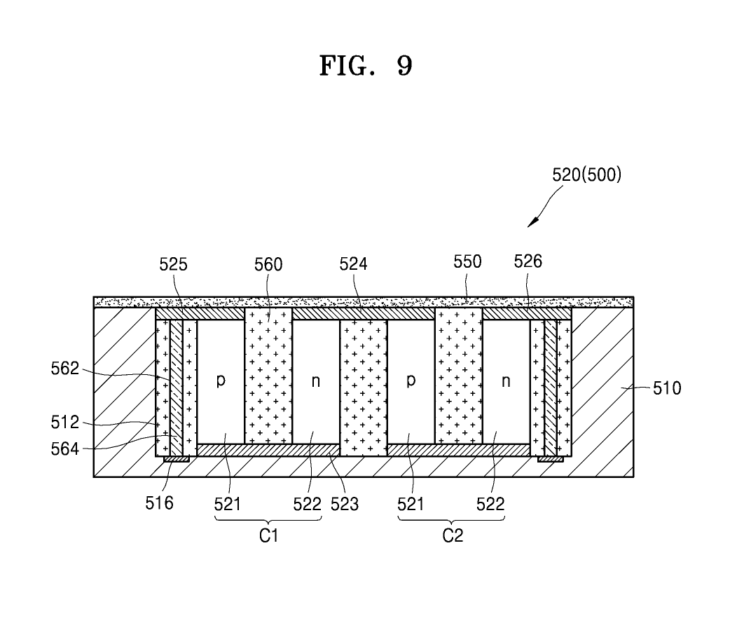

FIG. 9 is a schematic plan view of a wearable device 500 having a thermoelectric generator 520 according to another example. Like reference numerals are used to indicate elements that are substantially identical to the elements of FIG. 7, and thus detailed descriptions of these elements are not repeated for brevity.

Referring to FIG. 9, the thermoelectric generator 520 that is seated in an opening groove 512 formed in a strap 510 that includes at least one cell. In FIG. 9, for convenience of description, two cells, that is, a first cell C1 and a second cell C2, are shown. The first cell C1 and the second cell C2 each include a p-type semiconductor 521 and an n-type semiconductor 522. In the example of FIG. 9, insulating layers 560 are formed between the p-type semiconductor 521 and the n-type semiconductor 522 of each of the first cell C1 and the second cell C2 and on an outer circumference of the first cell C1 and the second cell C2. Additionally, metal vias 564 are formed in the insulating layers 560 so as to correspond to a p-type terminal 525 and the n-type terminal 526, by filling through holes 562. Also, in such an example, conductive units 516 are formed on a bottom of the opening groove 512 in the strap 510 and contact the metal via 564. For example, the conductive units 516 are electrically connected to another thermoelectric generator 520 or a charge unit 103, with reference to FIG. 4. For example, the thermoelectric generator 520 is fixed on the bottom of the opening groove 512 by using an adhesive, not shown.

In this example, a protection member 550 is formed on the thermoelectric generator 520. However, the protection member 550 according to the other example is not limited thereto. The heat sink 350, with reference to FIG. 7, is optionally disposed instead of the protection member 550 to cover the thermoelectric generator 520. An adhesive, not shown, is optionally formed between the heat sink 350 and the thermoelectric generator 520 so as to fix the heat sink 350 on an upper part of the thermoelectric generator 520. In some examples, the adhesive is a TIM.

As described according to the above examples, in a thermoelectric generator of a wearable device according to examples, a low temperature unit is almost exposed to the outside. Accordingly, the temperature of the low temperature unit is reduced by wind and air circulation, and thus, a temperature difference between a high temperature unit and the low temperature unit is maintained at a certain level. Therefore, the power generation efficiency of the thermoelectric generator of the wearable device is increased due to the maintained larger temperature difference.

Unless indicated otherwise, a statement that a first layer is “on” a second layer or a substrate is to be interpreted as covering both a case where the first layer is directly contacts the second layer or the substrate, and a case where one or more other layers are disposed between the first layer and the second layer or the substrate.

The spatially-relative expressions such as “below”, “beneath”, “lower”, “above”, “upper”, and the like may be used to conveniently describe relationships of one device or elements with other devices or among elements. The spatially-relative expressions should be understood as encompassing the direction illustrated in the drawings, added with other directions of the device in use or operation. Further, the device may be oriented to other directions and accordingly, the interpretation of the spatially-relative expressions is based on the orientation.

The expression such as “first conductivity type” and “second conductivity type” as used herein may refer to the conductivity types such as N or P types which are opposed to each other, and an example explained and exemplified herein encompasses complementary examples thereof.

As a non-exhaustive illustration only, a terminal/device/unit described herein may refer to mobile devices such as, for example, a cellular phone, a smart phone, a wearable smart device (such as, for example, a ring, a watch, a pair of glasses, a bracelet, an ankle bracket, a belt, a necklace, an earring, a headband, a helmet, a device embedded in the cloths or the like), a personal computer (PC), a tablet personal computer (tablet), a phablet, a personal digital assistant (PDA), a digital camera, a portable game console, an MP3 player, a portable/personal multimedia player (PMP), a handheld e-book, an ultra mobile personal computer (UMPC), a portable lab-top PC, a global positioning system (GPS) navigation, and devices such as a high definition television (HDTV), an optical disc player, a DVD player, a Blu-ray player, a setup box, or any other device capable of wireless communication or network communication consistent with that disclosed herein. In a non-exhaustive example, the wearable device may be self-mountable on the body of the user, such as, for example, the glasses or the bracelet. In another non-exhaustive example, the wearable device may be mounted on the body of the user through an attaching device, such as, for example, attaching a smart phone or a tablet to the arm of a user using an armband, or hanging the wearable device around the neck of a user using a lanyard.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A wearable device comprising:
a main body having at least one opening;
a thermoelectric generator that is seated in the opening and comprises a pair of terminals that are electrically connected to an adjacent thermoelectric generator or a charge unit that is disposed on the main body; and
a supporting member that is in contact with the skin of a user on a lower part of the thermoelectric generator,
wherein the thermoelectric generator comprises a high temperature unit and a low temperature unit facing each other, and the high temperature unit is disposed on the supporting member and the low temperature unit is disposed to face an outside environment.

2. The wearable device of claim 1, wherein the supporting member comprises:
a pair of vertical units that extend perpendicularly to the supporting member from the supporting member; and
a pair of protrusion units that extend towards opposite sides of the opening from an upper part of the vertical units,
wherein the main body comprises a pair of grooves to correspond to the pair of protrusion units, the pair of protrusion units being inserted into the pair of grooves.

3. The wearable device of claim 2, wherein the pair of terminals are inserted into the pair of grooves.

4. The wearable device of claim 3, wherein the pair of terminals are respectively disposed on the pair of protrusion units.

5. The wearable device of claim 1, wherein the pair of terminals comprises a p-type terminal and an n-type terminal, and the n-type terminal is electrically connected to a p-type terminal of another thermoelectric generator in an adjacent opening.

6. The wearable device of claim 1, wherein the supporting member is formed of plastic.

7. The wearable device of claim 1, further comprising a protection member or a heat sink situated on the thermoelectric generator.

8. The wearable device of claim 7, wherein the heat sink is formed of a material comprising one or more of a metal, carbon, carbon nanotubes (CNT), graphite, and graphene.

9. The wearable device of claim 1, further comprising a plurality of metal vias that fill a plurality of through holes in the supporting member, wherein the metal vias are in contact with the high temperature unit and are configured to transmit heat of the user's skin to the high temperature unit.

10. The wearable device of claim 1, wherein the main body is a strap that surrounds a wrist or a head of a human or an animal, and the opening and the thermoelectric generator are formed to be longer in a width direction of the strap.

11. A wearable device comprising:
a main body comprising at least one opening groove formed along a surface of the main body away from the body of a user; and
a thermoelectric generator comprising a high temperature unit on a bottom of the opening groove and a low temperature unit facing an outside environment,
wherein the thermoelectric generator comprises a pair of terminals that are electrically connected to an adjacent thermoelectric generator or a charge unit disposed on the main body.

12. The wearable device of claim 11, wherein the pair of terminals of the thermoelectric generator is inserted into a corresponding pair of sidewall grooves that is formed in sidewalls of the opening groove and is electrically connected to a conductive unit disposed in the corresponding pair of sidewall grooves.

13. The wearable device of claim 11, wherein the pair of terminals comprises a p-type terminal and an n-type terminal, and the n-type terminal is connected to a p-type terminal of another thermoelectric generator disposed in an adjacent opening groove.

14. The wearable device of claim 11, further comprising a protection member or a heat sink situated on the thermoelectric generator.

15. The wearable device of claim 11, wherein the heat sink is formed of a material comprising one or more of a metal, carbon, carbon nanotubes (CNT), graphite, and graphene.

16. The wearable device of claim 11, further comprising a plurality of first metal vias that fill a plurality of through holes formed on a bottom of the opening groove in the main body, wherein the first metal vias are in contact with the high temperature unit and are configured to transmit heat of the user's skin to the high temperature unit.

17. The wearable device of claim 11, wherein the main body is a strap that surrounds a wrist or a head of a human or an animal, and the opening and the thermoelectric generator are disposed to be longer in a width direction of the strap.

18. The wearable device of claim 11, wherein the pair of terminals is disposed on the surface of the main body away from a user's body, and further comprise a protection member that covers the low temperature unit and extends along at least a portion of the surface of the main body away from a user's body.

19. The wearable device of claim 11, further comprising:
an insulating layer that surrounds a gap between a p-type device and an n-type device and an outer circumference of the thermoelectric generator;
a pair of second metal vias formed in the insulating layer that are configured to respectively contact the pair of terminals; and
a pair of conductive units on a bottom of the opening groove and in contact with the pair of second metal vias.

20. A wearable device comprising:
a thermoelectric generator, comprising a high temperature unit and a low temperature unit, situated on a bottom of an opening of a main body having at least one opening, wherein the thermoelectric generator comprises a pair of terminals that is electrically connected to an adjacent thermoelectric generator or charge unit that is disposed on the main body; and
a supporting member that is in contact with the skin of a user on a lower part of the thermoelectric generator,
wherein the high temperature unit is disposed on the supporting member and the low temperature unit is disposed to face an outside environment.
